(19) United States
(12) Patent Application Publication
(10) Pub. No.: US 2025/0145877 A1
(43) Pub. Date: May 8, 2025

(54) THERMALLY CONDUCTIVE SILICONE COMPOSITION AND METHOD FOR PRODUCING THERMALLY CONDUCTIVE CURED PRODUCT USING THE COMPOSITION

(71) Applicant: Wacker Chemie AG, Munich (DE)

(72) Inventors: Kazuya SAKAI, Ibaraki (JP); Yurina SATO, Ibaraki (JP); Shunsuke YAMADA, Ibaraki (JP)

(73) Assignee: Wacker Chemie AG, Munich (DE)

(21) Appl. No.: 18/836,761

(22) PCT Filed: Jan. 18, 2023
(86) PCT No.: PCT/EP2023/051128

§ 371 Date: Aug. 8, 2024

(30) Foreign Application Priority Data
Feb. 22, 2022 (JP) 2022-026196

(51) Int. Cl. C09K 5/14; C08G 77/00; C08G 77/12; C08G 77/20; C08K 3/22; C08K 7/18; C09D 7/40; C09D 7/61; C09D 183/04

(52) U.S. Cl. CPC C09K 5/14; C08G 77/12; C08G 77/20; C09D 7/61; C09D 7/70; C09D 183/04; C08G 77/70; C08K 2003/2227; C08K 7/18; C08K 2201/001

(57) ABSTRACT

Provided is a thermally conductive insulating silicone composition that has favorable thermal conductivity and dispensing properties, has favorable resiliency after curing, and can secure adhesion even under application of impact. Also provided is a method for manufacturing such a thermally conductive insulating silicone composition. The thermally conductive silicone composition is applied in a liquid state to a substrate, and contains:

(A) a diorganopolysiloxane having an alkenyl group bonded to a silicon atom;

(B) a diorganopolysiloxane having a hydrogen atom bonded to a silicon atom;

(C) a thermally conductive filler;

(D) a silicone resin having at least one alkenyl group within one molecule, with a number-average molecular weight of 1,000 or more; and

(E) an addition reaction catalyst.

The content of the component (C) is 300 parts by mass or more and 2,000 parts by mass or less and the content of the component (D) is 1 part by mass or more, relative to 100 parts by mass of the total amount of the components (A) and (B).

### TECHNICAL FIELD

The present invention relates to a thermally conductive silicone composition having heat dissipation and insulating properties and containing a thermally conductive filler.

### BACKGROUND ART

As electronic components become smaller, higher in performance, and higher in output, the emitted thermal energy tends to increase, and the temperature of the electronic components tends to increase. In recent years, with the popularization of electric vehicles, high-performance batteries have been developed. In view of this background, various heat-dissipating silicone products have been developed for transferring heat generated by a heat generating body such as electronic components and batteries to a heat dissipation member such as a heat sink.

The heat-dissipating silicone products can be roughly classified into those provided in a sheet form such as a heat dissipation sheet and those provided in a liquid form or a paste form such as a gap filler, a heat dissipation oil compound, or a heat dissipation grease.

The heat dissipation sheet is a flexible and highly thermally conductive silicone rubber sheet obtained by curing a thermally conductive silicone composition into a sheet form. Therefore, such a heat dissipation sheet can be easily installed to come into close contact with the surface of a component, thereby enhancing the heat dissipation properties. However, the heat dissipation sheet cannot properly fit a component having a complicated shape or a material exhibiting a high degree of surface roughness, and in these cases, there is an unwanted possibility that minute voids are generated at the interface thereof.

On the other hand, the gap filler is obtained by applying, in a liquid or paste form, a thermally conductive silicone composition directly to a heat generating body or a heat dissipating body, and curing the composition after the application. Therefore, the use of a gap filler is advantageous in that even when the filler is applied to a complicated irregular shape, voids will be filled and a high heat dissipation effect will be exhibited.

In order for the gap filler to exhibit a higher heat dissipation effect, it is necessary to improve the thermal conductivity of the gap filler and also improve the adhesion at the contact interface between the heat generating body or the heat dissipation body and the gap filler. A constant amount of such a gap filler is applied at a predetermined position by a dispenser. Therefore, the gap filler needs to have an appropriate fluidity suitable for discharge by the dispenser.

In order to be used, the gap filler is compressed in a predetermined gap between the heat generating body and the heat dissipation body. However, when unintended impact is applied from a substrate while using the gap filler, there is a possibility that the gap filler will be crushed to form an air layer between the substrate and the gap filler.

For preventing separation of the gap filler from the substrate even under application of impact from the outside, a conventional countermeasure includes an enhancement in the adhesive properties of the gap filler. However, when the adhesive strength between the gap filler and the substrate is high, this countermeasure may destroy the substrate under application of impact. By using a material that has no adhesive properties and is resilient, the destruction of the substrate during application of impact is suppressed. Even when the gap filler is temporarily separated from the substrate, adhesion can be secured by the resiliency of the gap filler. When the air layer is formed, thermal resistance is increased, leading to a decrease in the heat dissipation properties of a battery, an electronic substrate, and the like and resulting in a decrease in processing speed.

A conventional countermeasure for improving the resiliency of the thermally conductive composition includes use of a sheet-shaped heat-dissipating material having resiliency. In order to improve the handleability of the sheet-shaped material, a certain degree of rigidity is required. However, when the hardness is high, the sheet-shaped material is difficult to crush.

For example, the invention described in Patent Literature 1 is characterized by containing a room-temperature-curable or heating-curable liquid silicone rubber that has an Asker C hardness, after curing, of 10 to 90 for improvement of resiliency of a thermally conductive sheet cured product.

The invention described in Patent Literature 2 is characterized by containing a methylhydrogenpolysiloxane, an epoxy group-containing alkyltrialkoxysilane, and a cyclic polysiloxane oligomer for improvement of resiliency and adhesive properties of a thermally conductive sheet cured product.

However, the heat-dissipating sheets in Patent Literatures 1 and 2 are a cured product during installation, and therefore the heat-dissipating sheets are difficult to crush when bringing them into close contact with an uneven structure on the substrate, and adhesion is difficult to achieve. A gap filler composition that is uncured during application and has impact resilience has not been known.

### CITATION LIST

### Patent Literature

PTL 1: Japanese Patent Application Laid-Open No. 2021-021047

PTL 2: Japanese Patent Application Laid-Open No. 2021-095569

### SUMMARY OF INVENTION

### Technical Problem

From the background described above, there is a demand for the development of a thermally conductive insulating silicone composition that has favorable thermal conductivity and dispensing properties, has favorable resiliency after curing, and can secure adhesion even under application of impact. The present invention has been made in view of the circumstances described above, and it is an object of the present invention to provide a thermally conductive silicone composition that firstly has more favorable thermal conductivity and dispensing properties as compared with a conventional thermally conductive silicone composition and secondly forms a gap filler having high resiliency after curing as well as a method for producing the same.

### Solution to Problem

The inventors have found that when a thermally conductive filler and a silicone resin are added to a silicone composition containing an organopolysiloxane, the problems of the present invention can be solved. Thus, the present invention has been completed.

A thermally conductive silicone composition according to the present invention is a composition for forming a gap filler. The gap filler is obtained by applying the thermally conductive silicone composition in a liquid state to a substrate followed by curing. The gap filler does not need handling after curing and therefore can have resiliency while having low hardness after curing.

When the gap filler has high resiliency, an air layer can be reduced, and low thermal resistance can be maintained.

A method for achieving resiliency includes introduction of a high molecular weight polymer. However, this method has a problem that viscosity is increased. According to the present invention, resiliency can be achieved without introducing a high molecular weight polymer.

That is, the present invention is a thermally conductive silicone composition that is applied in a liquid state to a substrate, the composition containing:
a component (A) that is a diorganopolysiloxane having an alkenyl group bonded to a silicon atom, with a viscosity, at 25° C., of 10 mPa·s or more and 1,000,000 mPa·s or less;
a component (B) that is a diorganopolysiloxane having a hydrogen atom bonded to a silicon atom, with a viscosity, at 25° C., of 10 mPa·s or more and 1,000,000 mPa·s or less;
a component (C) that is a thermally conductive filler;
a component (D) that is a silicone resin having at least one alkenyl group within one molecule, with a number-average molecular weight of 1,000 or more; and
a component (E) that is an addition reaction catalyst, wherein
the content of the component (C) is 300 parts by mass or more and 2,000 parts by mass or less relative to 100 parts by mass of the total amount of the components (A) and (B), and
the content of the component (D) is 1 part by mass or more relative to 100 parts by mass of the total amount of the components (A) and (B).

### Advantageous Effects of Invention

The thermally conductive silicone composition according to the present invention has characteristics such as favorable dispensing properties, a low hardness after curing, and favorable resiliency, and is useful as a thermally conductive silicone composition for forming a gap filler that is obtained by applying the thermally conductive silicone composition in a liquid state to a substrate by a dispenser, or the like.

### DESCRIPTION OF EMBODIMENTS

Hereinafter, a thermally conductive silicone composition and a method for producing a gap filler using the thermally conductive silicone composition according to the present invention will be described in detail. Herein, a thermally conductive filler is also simply referred to as a filler or filling material.

The thermally conductive silicone composition according to the present invention is a thermally conductive silicone composition that is applied in a liquid state to a substrate, and the composition can contain:
a component (A) that is a diorganopolysiloxane having an alkenyl group bonded to a silicon atom, with a viscosity, at 25° C., of 10 mPa·s or more and 1,000,000 mPa·s or less;
a component (B) that is a diorganopolysiloxane having a hydrogen atom bonded to a silicon atom, with a viscosity, at 25° C., of 10 mPa·s or more and 1,000,000 mPa·s or less;
a component (C) that is a thermally conductive filler;
a component (D) that is a silicone resin having at least one alkenyl group within one molecule, with a number-average molecular weight of 1,000 or more; and
a component (E) that is an addition reaction catalyst, wherein
the content of the component (C) is 300 parts by mass or more and 2,000 parts by mass or less relative to 100 parts by mass of the total amount of the components (A) and (B), and
the content of the component (D) is 1 part by mass or more relative to 100 parts by mass of the total amount of the components (A) and (B).

When the predetermined silicone resin of the component (D) is added to a composition containing the components (A), (B), (C), and (E), the resiliency of a gap filler to be obtained by curing can be enhanced while the viscosity of the thermally conductive silicone composition before curing is maintained to be low.

### Component (A)

The component (A), which is the main component of the thermally conductive silicone composition, is a diorganopolysiloxane having an alkenyl group bonded to a silicon atom and has a viscosity, at 25° C., of 10 mPa·s or more and 1,000,000 mPa·s or less.

As the diorganopolysiloxane, one type thereof may be used alone, or two or more types thereof may be used in combination as appropriate. The diorganopolysiloxane is the main component of the thermally conductive silicone composition (hereinafter which may be simply referred to as a silicone composition) and has at least one alkenyl group bonded to a silicon atom within one molecule on average, preferably 2 to 50 alkenyl groups, and more preferably 2 to 20 alkenyl groups.

The component (A) does not have a specifically limited molecular structure, and may have, for example, a linear structure, a partially branched linear structure, a branched chain structure, a cyclic structure, or a branched cyclic structure. Among these, the component (A) is preferably a substantially linear organopolysiloxane, and specifically, the component (A) is preferred to be a linear diorganopolysiloxane in which the molecular chain is mainly composed of a diorganosiloxane repeat unit and of which both terminals of the molecular chain are blocked with a triorganosiloxy group. Some or all of the molecular chain terminals, or some of the side chains, may be an Si—OH group.

The component (A) may be a polymer composed of a single type of siloxane unit or a copolymer composed of two or more types of siloxane units. The position of the alkenyl group bonded to the silicon atom in the component (A) is not particularly limited, and the alkenyl group may be bonded to the silicon atom at the molecular chain terminal, to the silicon atom at a non-terminal molecular chain site (in the middle of the molecular chain), or to both.

The viscosity of the component (A) at 25° C. is 10 mPa·s or more and 1,000,000 mPa·s or less, preferably 20 mPa·s or more and 500,000 mPa·s or less, and more preferably 50 mPa·s or more and 10,000 mPa·s or less. When the viscosity thereof falls within the above-mentioned viscosity range, it is possible to suppress occurrence of a phenomenon in which the filler of the components (C) and (D), which will be described later, tends to precipitate in the obtained thermally conductive silicone composition due to the too-low viscosity of the component (A). Accordingly, a thermally conductive silicone composition having excellent long-term storage stability can be obtained. In addition, when the viscosity thereof falls within the above-described range, since an appropriate fluidity of the obtained silicone composition can be obtained, it is possible to increase the fluid ejection properties as well as the productivity.

In order to adjust the viscosity (mixing viscosity), before curing, of the thermally conductive silicone composition that is a final product, two or more types of diorganopolysiloxanes having an alkenyl group and having different viscosities can also be used.

In order to achieve both long-term storage stability and appropriate fluidity, it is more preferable that a diorganopolysiloxane having a viscosity at 25° C. of 100,000 mPa·s or more be not contained, and it is more preferable that a diorganopolysiloxane having a viscosity of 10,000 mPa·s or more be not contained.

As the viscosity of the component (A) is lower, a larger amount of the silicone resin as the component (D) can be added. This makes it possible to further enhance resiliency. For example, when the viscosity at 25° C. of the component (A) is 10,000 mPa·s, the silicone resin as the component (D) can be added in an amount of 4 parts by mass or more relative to 100 parts by mass of the total amount of the components (A) and (B). When the viscosity of the component (A) is 120 mPa·s, 10 parts by mass or more of the silicone resin as the component (D) can be added.

Specifically, the component (A) is represented by the following general formula (1) as an average composition formula:

R¹ₐSiO_{(4-a)/2} (1)

(In the formula (1), R¹s are the same as or different from each other and each are an unsubstituted or substituted monovalent hydrocarbon group having 1 to 18 carbon atoms, and a is 1.7 to 2.1, preferably 1.8 to 2.5, and more preferably 1.95 to 2.05.).

In one embodiment, at least two or more of the monovalent hydrocarbon groups represented by the aforementioned R¹ are selected from alkenyl groups such as a vinyl group, an allyl group, a propenyl group, an isopropenyl group, a butenyl group, an isobutenyl group, a hexenyl group, and a cyclohexenyl group. Groups other than these groups are substituted or unsubstituted monovalent hydrocarbon groups having 1 to 18 carbon atoms. Specifically, the aforementioned R¹ is selected from the group consisting of an alkyl group such as a methyl group, an ethyl group, a propyl group, an isopropyl group, a butyl group, an isobutyl group, a tert-butyl group, a pentyl group, a neopentyl group, a hexyl group, a 2-ethylhexyl group, a heptyl group, an octyl group, a nonyl group, a decyl group, and a dodecyl group; a cycloalkyl group such as a cyclopentyl group, a cyclohexyl group, and a cycloheptyl group; an aryl group such as a phenyl group, a tolyl group, a xylyl group, a biphenyl group, and a naphthyl group; an aralkyl group such as a benzyl group, a phenylethyl group, a phenylpropyl group, and a methylbenzyl group; and a halogen-substituted or cyano-substituted alkyl group in which a part or all of hydrogen atoms in the above-described hydrocarbon groups have been substituted with a halogen atom, a cyano group, or the like, such as a chloromethyl group, a 2-bromoethyl group, a 3,3,3-trifluoropropyl group, a 3-chloropropyl group, and a cyanoethyl group.

R¹s to be selected preferably include a vinyl group as the two or more alkenyl groups required, and a methyl group, a phenyl group, or a 3,3,3-trifluoropropyl group as the other groups. In addition, it is preferable that 70 mol % or more of R¹s be a methyl group, in consideration of physical properties and economic efficiency of the cured product, and normally, it is preferable that 80 mol % or more of R¹s be a methyl group.

Specific examples of the molecular structure of the component (A) include a dimethylpolysiloxane with both molecular chain terminals blocked with a dimethylvinylsiloxy group, a dimethylsiloxane-methylphenylsiloxane copolymer with both molecular chain terminals blocked with a dimethylvinylsiloxy group, a dimethylsiloxane-methylvinylsiloxane copolymer with both molecular chain terminals blocked with a dimethylvinylsiloxy group, a dimethylsiloxane-methylvinylsiloxane-methylphyenylsiloxane copolymer with both molecular chain terminals blocked with a dimethylvinylsiloxy group, a dimethylsiloxane-methylvinylsiloxane copolymer with both molecular chain terminals blocked with a trimethylsiloxy group, an organopolysiloxane composed of a siloxane unit represented by the formula: (CH₃)₂ViSiO_{1/2}, a siloxane unit represented by the formula: (CH₃)₃SiO_{1/2}, and a siloxane unit represented by the formula: SiO_{4/2} (Vi in the formula represents a vinyl group), an organopolysiloxane in which part or all of the methyl groups in the above-mentioned organopolysiloxanes are substituted by an alkyl group such as an ethyl group or a propyl group, an aryl group such as a phenyl group or a tolyl group, and a halogenated alkyl group such as a 3,3,3-trifluoropropyl group, and mixtures of two or more of these organopolysiloxanes. From the viewpoint of enhancing elongation at the time of breakage of the cured product due to increased molecular chain length, a linear diorganopolysiloxane with a vinyl group at both molecular chain terminals is preferable.

These diorganopolysiloxanes may be commercially available or prepared by methods known to those skilled in the art.

The content of the diorganopolysiloxane of the component (A), relative to 100 parts by mass of the total amount of the components (A) and (B) in the silicone composition of the present invention, is preferably 2 parts by mass or more and 90 parts by mass or less, and more preferably 30 parts by mass or more and 80 parts by mass or less. When the content thereof falls within the aforementioned range, the viscosity of the entire silicone composition can fall within an appropriate range, and the thermally conductive silicone composition can exhibit excellent long-term storage stability, can suppress the phenomenon of flowing out after application to a substrate, and can maintain high thermal conductivity due to appropriate fluidity.

### Component (B)

The component (B) is a diorganopolysiloxane having a hydrogen atom bonded to a silicon atom. The component (B) has a viscosity, at 25° C., of 10 mPa·s or more and 1,000,000 mPa·s or less.

The component (B) is a diorganopolysiloxane having one or more hydrogen atoms bonded to silicon atoms in one molecule, and acts as a cross-linking agent for curing the silicone composition according to the present invention.

The number of hydrogen atoms bonded to silicon atoms is not particularly limited as long as it is one or more, and may be two or more and four or less. The component (B) that is linear may have a hydrogen atom bonded to a silicon atom at each of both terminals, that is, may have two hydrogen atoms bonded to silicon atoms in the molecule.

The component (B) may be any diorganopolysiloxane as long as it contains one or more hydrogen atoms (SiH groups) bonded to silicon atoms within one molecule. Examples thereof that can be used include a dimethylsiloxane-methylhydrogensiloxane copolymer, a methylphenylsiloxane-methylhydrogensiloxane copolymer, and a copolymer composed of a dimethylhydrogensiloxy unit and an SiO_{4/2} unit. As the component (B), one type thereof may be used alone, or two or more types thereof may be used in combination as appropriate.

The molecular structure of the component (B) is not particularly limited, and may be, for example, a linear, branched, cyclic, or three-dimensional network structure. Specifically, the structure represented by the following average composition formula (2) can be used:

R³ₚH_{q}SiO_{(4-p-q)/2} (2)

(In the formula, R³ is an unsubstituted or substituted monovalent hydrocarbon group excluding an aliphatic unsaturated hydrocarbon group, p is 0 to 3.0, preferably 0.7 to 2.1, q is 0.0001 to 3.0, preferably 0.001 to 1.0, and p+q is a positive number satisfying 0.5 to 3.0, preferably 0.8 to 3.0.).

Examples of R³ in the formula (2) include non-substituted or halogen-substituted monovalent hydrocarbon groups and the like having 1 to 10 carbon atoms, preferably 1 to 8 carbon atoms excluding an aliphatic unsaturated hydrocarbon group. Specific examples thereof include an alkyl group such as a methyl group, an ethyl group, a propyl group, a butyl group, a pentyl group, a hexyl group, an isopropyl group, an isobutyl group, a tert-butyl group, and a cyclohexyl group; an aryl group such as a phenyl group, a tolyl group, and a xylyl group; an aralkyl group such as a benzyl group and a phenethyl group; and an alkyl halide group such as a 3-chloropropyl group and a 3,3,3-trifluoropropyl group. Among these, a methyl group, an ethyl group, a propyl group, a phenyl group, and a 3,3,3-trifluoropropyl group are preferable, and a methyl group is particularly preferable.

Specific examples of the component (B) include 1,1,3,3-tetramethyldisiloxane, 1,3,5,7-tetramethylcyclotetrasiloxane, a methylhydrogencyclopolysiloxane, a methylhydrogensiloxane-dimethylsiloxane cyclic copolymer, tris(dimethylhydrogensiloxy)methylsilane, tris(dimethylhydrogensiloxy)phenylsilane, a dimethylsiloxane-methylhydrogensiloxane copolymer with both molecular chain terminals blocked with a dimethylhydrogensiloxy group, a methylhydrogenpolysiloxane with both molecular chain terminals blocked with a dimethylhydrogensiloxy group, a methylhydrogenpolysiloxane with both molecular chain terminals blocked with a trimethylsiloxy group, a dimethylpolysiloxane with both molecular chain terminals blocked with a dimethylhydrogensiloxy group, a dimethylsiloxane-diphenylsiloxane copolymer with both molecular chain terminals blocked with a dimethylhydrogensiloxy group, a dimethylsiloxane-methylhydrogensiloxane copolymer with both molecular chain terminals blocked with a trimethylsiloxy group, a dimethylsiloxane-diphenylsiloxane-methylhydrogensiloxane copolymer with both molecular chain terminals blocked with a trimethylsiloxy group, a dimethylsiloxane-methylhydrogensiloxane copolymer with both molecular chain terminals blocked with a dimethylhydrogensiloxy group, a copolymer of a H(CH₃)₂SiO_{1/2} unit and an SiO₂ unit, a copolymer of a H(CH₃)₂SiO_{1/2} unit, a (CH₃)₃SiO_{1/2} unit, and an SiO₂ unit, and mixtures of two or more of these diorganopolysiloxanes.

In the silicone composition described above, the content of the component (B) is preferably in such a range that the ratio of the number of SiH groups in the component (B) to that of the alkenyl group in the component (A) falls within the range of 1/5 to 7, more preferably within the range of 1/2 to 2, and still more preferably within the range of 3/4 to 5/4. When the content of the component (B) falls within the aforementioned range, the silicone composition is sufficiently cured and the hardness of the entire silicone composition becomes a more preferable range, so that cracks are less likely to occur when a thermally conductive member, which is obtained by curing the composition, is used as a gap filler. In addition to these, there is an advantage that the silicone composition dose not sag and can maintain its retention ability in the vertical direction even when the substrate is disposed in a vertical orientation (erected).

The SiH group in the component (B) may be bonded to the molecular chain terminals, may be bonded to side chains, or may be bonded to both the molecular chain terminals and the side chains. It is preferable to use a mixture of a diorganopolysiloxane having an SiH group only at the molecular chain terminals and a diorganopolysiloxane having an SiH group only on the side chain of the molecular chain.

The diorganopolysiloxane having an SiH group only at the molecular chain terminals has an advantage that the diorganopolysiloxane has high reactivity due to low steric hindrance, and the diorganopolysiloxane having an SiH group at the side chains contributes to network construction by a crosslinking reaction and thus has an advantage of improving the strength of the thermally conductive member. In order to impart flexibility after curing, it is preferable to use a diorganopolysiloxane having an SiH group only at the molecular chain terminals.

From the viewpoint of improving adhesive properties and heat resistance, the component (B) may include an organohydrogenpolysiloxane having a trimethylsiloxy group at both the molecular chain terminals and at least one aromatic group contained within the molecule. For economic reasons, the aromatic group is more preferably a phenyl group.

The viscosity of the diorganopolysiloxane of the component (B) at 25° C. is 10 mPa·s or more and 1,000,000 mPa·s or less, preferably 20 mPa·s or more and 500,000 mPa·s or less, and more preferably 50 mPa·s or more and 10,000 mPa·s or less.

In order to adjust the viscosity of the silicone composition which is a final product, it is also possible to use two or more types of diorganopolysiloxanes having a hydrogen atom and having respective different viscosities.

The content of the diorganopolysiloxane of the component (B), relative to 100 parts by mass of the total amount of the components (A) and (B) in the silicone composition of the present invention, is preferably 10 parts by mass or more and 98 parts by mass or less, and more preferably 20 parts by mass or more and 90 parts by mass or less. When the viscosity falls within the aforementioned range, the hardness of the cured silicone composition can fall within an appropriate range. In addition, the cured silicone composition can exhibit flexibility and robustness.

### Component (C)

The thermally conductive filler of the component (C) is a filling material component that improves the thermal conductivity of the silicone composition and the shape retentivity. As the component (C), a thermally conductive filler containing at least one selected from the group consisting of a metal, an oxide, a hydroxide, and a nitride can be used.

In order to obtain a gap filler having high insulation properties for application to an electronic substrate or the like, it is preferable to use an inorganic material having excellent insulation properties as well as thermal conductivity as the thermally conductive filler of the component (C).

The shape of the component (C) is not particularly limited, and may be spherical, amorphous, or fibrous.

Examples of the thermally conductive fillers of the component (C) include a metal oxide such as aluminum oxide, zinc oxide, magnesium oxide, titanium oxide, silicon oxide, and beryllium oxide; a metal hydroxide such as aluminum hydroxide and magnesium hydroxide; a nitride such as aluminum nitride, silicon nitride, and boron nitride; a carbide such as boron carbide, titanium carbide, and silicon carbide; graphite; a metal such as aluminum, copper, nickel, and silver; and mixtures thereof. In particular, when electrical insulation properties are required for the silicone composition, the component (C) is preferably a metal oxide, a metal hydroxide, a nitride, or a mixture thereof, and it may be an amphoteric hydroxide or an amphoteric oxide. Specifically, it is preferable to use one or more types selected from the group consisting of aluminum hydroxide, boron nitride, aluminum nitride, zinc oxide, aluminum oxide, magnesium oxide, and magnesium hydroxide.

It should be noted that aluminum oxide is an insulating material, has relatively good compatibility with the components (A) and (B), can be industrially selected from a wide variety of particle diameters, is a readily available resource, is relatively inexpensive, and is therefore suitable as the thermally conductive inorganic filler.

When aluminum oxide is used as the component (C), aluminum oxide with a spherical shape or an amorphous shape is preferably used. Spherical aluminum oxide is α-alumina obtained mainly by high temperature thermal spraying or hydrothermal treatment of alumina hydrate. Herein, the spherical shape may be not only a true spherical shape but also a rounded shape.

The average particle diameter of the component (C) is not particularly limited, and may be in the range of, for example, 0.1 μm or more and 500 μm or less, preferably 0.5 μm or more and 200 μm or less, and more preferably 1.0 μm or more and 100 μm or less. If the average particle diameter is too small, the fluidity of the silicone composition is lowered. If the average particle diameter is too large, the dispensing properties are lowered, and there is a possibility that problems such as scraping of the apparatus are caused by being caught in the sliding portion of a coating apparatus. In the present invention, the average particle diameter of the component (C) is defined by D50 (or median diameter) which is a 50% particle diameter in the volume-based cumulative particle size distribution measured by a laser diffraction particle size measuring apparatus.

As the component (C), only a spherical filler or only an amorphous filler may be used, or the spherical filler and the amorphous filler may be used in combination. When at least two or more types of fillers having different shapes are used in combination, the composition can be filled with the fillers in a state close to close packing, so that thermal conductivity is further increased. When the proportion of a thermally conductive spherical filler is 30% by mass or more relative to 100% by mass of the whole component (C) during use of the thermally conductive spherical filler in combination with a thermally conductive amorphous filler, thermal conductivity can be further increased.

The BET specific surface area of the component (C) is not particularly limited. For example, the BET specific surface area of the spherical filler is preferably 1 m²/g or less, and more preferably 0.5 m²/g or less. The BET specific surface area of the amorphous filler is preferably 5 m²/g or less, and more preferably 3 m²/g or less.

When only the amorphous filler having a BET specific surface area of more than 5 m²/g is added, the viscosity of the thermally conductive composition is increased, and the adhesion of the thermally conductive composition to the substrate after curing is impaired. As a result, heat dissipation properties are impaired. When the composition is densely filled with a bulky filler, the motion of silicone rubber molecules in the composition is disturbed, and resiliency is impaired. In the present invention, the BET specific surface area of the component (C) is a value obtained by measuring the amount of gas physically adsorbed to the surface of particles in a low-temperature state and calculating a specific surface area.

In order to improve dispersibility and increase the filling properties of the filler, at least a part of the surface of the thermally conductive filler may be subjected to a surface treatment or coated. Any previously known surface treatment and coating may be suitable.

In the silicone composition of the present

invention, the content of the component (C), relative to 100 parts by mass of the total amount of the components (A) and (B), is preferably 200 parts by mass or more and 3,000 parts by mass or less, more preferably 300 parts by mass or more and 2,000 parts by mass or less, even more preferably 400 parts by mass or more and 1,500 parts by mass or less, and may be 1,000 parts by mass or less. When the content of the component (C) falls within the aforementioned range, the silicone composition as a whole has sufficient thermal conductivity. In addition, mixing of the component (C) can be facilitated, flexibility even after curing can be maintained, and the specific gravity of the cured product does not become too large. Thus, the silicone composition is more suitable as a gap filler composition for which thermal conductivity and weight reduction are required. If the content of the component (C) is too small, difficulties occur in sufficiently increasing the thermal conductivity of the resulting cured product of the silicone composition. If the content of the component (C) is too large, the silicone composition becomes highly viscous, which may make uniform application of the silicone composition difficult, resulting in problems in that thermal resistance of the cured product of the composition increases and flexibility thereof decreases.

### Component (D)

For use in the present invention, the silicone resin of the component (D) has at least one alkenyl group within one molecule and a number-average molecular weight of 1,000 or more. The component (D) is added to impart resiliency to the gap filler obtained by curing the thermally conductive silicone composition in the present invention. In the thermally conductive silicone composition according to the present invention, the component (D) undergoes a reaction with the surface of the thermally conductive filler of the component (C) resulting in a bond between the component (D) and the surface of the component (C). The alkenyl group in the component (D) undergoes a crosslinking reaction with the components (A) and (B). The resulting three-dimensional crosslinking structure of the gap filler obtained by curing is thought to be rigid and exhibit resiliency.

Further detail is as follows. Since an OH group on the surface of the component (C) can undergo a reaction with an OH group, an SiH group, and the like contained in the component (D), the component (D) is bonded to the surface of the component (C). Since the alkenyl group in the component (D) can undergo a reaction with an SiH group in the component (B), the component (B) undergoes a crosslinking reaction with not only the component (A) but also the component (D) bonded to the component (C). Thus, in the thermally conductive silicone composition according to the present invention, the components (A), (B), (C), and (D) interact with one another to form a crosslinking structure, so that resiliency is exhibited.

In the present invention, it is not necessary that a high-viscosity polymer be added to impart resiliency. Therefore, even while maintaining a low viscosity of the thermally conductive silicone composition of the present invention before curing, resiliency can be imparted to the gap filler obtained after curing. When the viscosity of the thermally conductive silicone composition is low, favorable dispensing properties are exhibited during application of the thermally conductive silicone composition to a substrate, and fine voids can also be filled with the thermally conductive silicone composition. Therefore, adhesion can be enhanced. When the gap filler has resiliency, the formation of an air layer between the substrate and the gap filler can be suppressed, and low thermal resistance can be maintained.

The number-average molecular weight of the component (D) is not particularly limited as long as it is 1,000 or more. The number-average molecular weight thereof is preferably 1,000 or more and 10,000 or less, and more preferably 2,000 or more and 8,000 or less. When the number-average molecular weight is within the above-described range, the gap filler obtained by curing has favorable resiliency.

The component (D) in the present invention has one or more alkenyl groups bonded to silicon atoms within one molecule and contains 80 mol % or more of one or more units selected from the group consisting of an R²₃SiO_{1/2} unit (M unit), an R²₂SiO_{2/2} unit (D unit), an R²SiO_{3/2} unit (T unit), and an SiO_{4/2} unit (Q unit). The component (D) may be a silicone resin represented by MQ, MDQ, MT, MDT, MTDQ, or DQ.

The component (D) in the present invention may be a DT silicone resin containing a D unit and a T unit in an amount of 80 mol % or more, preferably 95 mol % or more, and more preferably 97 mol % or more. The molar ratio represented by (D unit)/(T unit) is preferably 0.01 or more and 5.0 or less, more preferably 0.2 or more and 3.5 or less, and further preferably 0.2 or more and 0.5 or less.

The component (D) in the present invention may be an MQ silicone resin containing an M unit and a Q unit in an amount of 80 mol % or more, preferably 95 mol % or more, and more preferably 97 mol % or more.

In particular, when the component (D) contains a silicone resin constituted of an MQ unit containing an M unit and a Q unit, a three-dimensional crosslink density is increased., and higher resiliency is thus achieved. The molar ratio represented by (M unit)/(Q unit) in the silicone resin is preferably 0.1 or more and 3.0 or less, more preferably 0.3 or more and 2.5 or less, and further preferably 0.4 or more and 2.2 or less.

Since the component (D) in the present invention has an alkenyl group, the affinity of the component (D) to a polymer component having a silicone skeleton (the components (A) and (B)) is favorable, allowing for further improvement in the uniformity of the composition.

Among the monovalent hydrocarbon groups represented by R² described above, at least one or more groups are selected from an alkenyl group such as a vinyl group, an allyl group, a propenyl group, an isopropenyl group, a butenyl group, an isobutenyl group, a hexenyl group, and a cyclohexenyl group, and the other group is a substituted or unsubstituted monovalent hydrocarbon group having 1 to 18 carbon atoms. Specifically, it is selected from an alkyl group such as a methyl group, an ethyl group, a propyl group, an isopropyl group, a butyl group, an isobutyl group, a tert-butyl group, a pentyl group, a neopentyl group, a hexyl group, a 2-ethylhexyl group, a heptyl group, an octyl group, a nonyl group, a decyl group, and a dodecyl group, a cycloalkyl group such as a cyclopentyl group, a cyclohexyl group, and a cycloheptyl group, an aryl group such as a phenyl group, a tolyl group, a xylyl group, a biphenyl group, and a naphthyl group, an aralkyl group such as a benzyl group, a phenylethyl group, a phenylpropyl group, and a methylbenzyl group, and a halogen-substituted alkyl group and a cyano-substituted alkyl group in which some or all of the hydrogen atoms in these hydrocarbon groups are replaced by a halogen atom, a cyano group, or the like, such as a chloromethyl group, a 2-bromoethyl group, a 3,3,3-trifluoropropyl group, a 3-chloropropyl group, and a cyanoethyl group.

R²s to be selected preferably include a vinyl group as the alkenyl group, and a methyl group, a phenyl group, or a 3,3,3-trifluoropropyl group as the other group.

The number of the alkenyl groups in Res within one molecule is preferably 1 or more and 20 or less, and further preferably 1 or more and 15 or less.

The amount of the OH group in the silicone resin is not particularly limited, and for example, may be 0.01% or more and 3.0% or less, more preferably 0.05% or more and 2.0% or less, and further preferably 0.1% or more and 1.0% or less.

The added amount of the component (D) is not particularly limited as long as it is 1 part by mass or more relative to 100 parts by mass of the total amount of the components (A) and (B), and can be adjusted according to properties of the component (D), the viscosities of the components (A) and (B), and the like. The amount thereof is preferably 2 parts by mass or more and 12 parts by mass or less, and more preferably 2 parts by mass or more and 10 parts by mass or less. When the added amount of the component (D) falls within the above-described range, excessive increases in viscosity and hardness can be suppressed, and sufficient resiliency is achieved. The Asker C hardness after curing may be 40 to 70. When the Asker C hardness falls within this range, followability with respect to vibration and displacement of the substrate after curing is favorable. When the hardness is too high, flexibility is decreased, and followability may be impaired. When the hardness is too low, a pumping-out phenomenon may occur. The component (D) itself is a solid or a viscous liquid at room temperature, but the component (D) may be dissolved in a solvent and used. In this case, the amount of the component (D) added to the composition is determined to be the amount of the component (D) except for the amount of the solvent.

As the solvent that dissolves the component (D), an organic solvent such as toluene or xylene or a silicone-based solvent such as hexamethyl cyclotrisiloxane, octamethyl cyclotetrasiloxane, or decamethyl cyclopentasiloxane can be used. In particular, since an organic solvent such as toluene and xylene has volatility, the usage environment of the organic solvent is limited. Furthermore, a diorganopolysiloxane having an alkenyl group functions as a polymer component, and is thus suitable.

When the total amount of the components (A) and (B) is 100 parts by mass, the multiplicative product of the amount of the component (D) contained in parts by mass with the number-average molecular weight of the component (D) may be 3,000 or more. The multiplicative product of the amount of the component (D) contained in parts by mass with the number-average molecular weight of the component (D) is preferably 3,000 or more and 30,000 or less, more preferably 4,000 or more and 20,000 or less, and further preferably 5,000 or more and 15,000 or less.

When the multiplicative product falls within the above-described range, even if a smaller amount of silicone resin having a relatively higher number-average molecular weight is used, the resiliency of the gap filler can be properly exhibited. When the added amount of the component (D) is reduced, an excessive increase in the viscosity of the thermally conductive silicone composition before curing can be suppressed.

On the other hand, when a silicone resin having a relatively lower number-average molecular weight is used, the silicone resin in a relatively larger added amount can achieve an effect of further enhancing resiliency.

### Component (E)

The addition reaction catalyst of the component (E) is a catalyst that promotes an addition-curing reaction between an alkenyl group bonded to a silicon atom in the component (A) described above and a hydrogen atom bonded to a silicon atom in the component (B) described above, and is a catalyst known to those skilled in the art. Examples of the component (E) include a platinum group metal such as platinum, rhodium, palladium, osmium, iridium, and ruthenium, and catalysts in which any of the aforementioned metals is supported by a particulate carrying material (for example, activated carbon, aluminum oxide, and silicon oxide).

Furthermore, examples of the component (E) include a platinum halide, a platinum-olefin complex, a platinum-alcohol complex, a platinum-alcoholate complex, a platinum-vinylsiloxane complex, dicyclopentadiene-platinum dichloride, cyclooctadiene-platinum dichloride, and cyclopentadiene-platinum dichloride.

In addition, from an economic viewpoint, a metal compound catalyst other than platinum group metals as described above may be used. Examples of the iron catalyst for hydrosilylation include an iron-carbonyl complex catalyst, an iron catalyst having a cyclopentadienyl group as a ligand, an iron catalyst having a terpyridine-based ligand or a combination of a terpyridine-based ligand and a bistrimethylsilylmethyl group, an iron catalyst having a bisiminopyridine ligand, an iron catalyst having a bisiminoquinoline ligand, an iron catalyst having an aryl group as a ligand, an iron catalyst having a cyclic or acyclic olefin group with an unsaturated group, and an iron catalyst having a cyclic or acyclic olefinyl group with an unsaturated group. Other examples of the catalyst for hydrosilylation include a cobalt catalyst, a vanadium catalyst, a ruthenium catalyst, an iridium catalyst, a samarium catalyst, a nickel catalyst, and a manganese catalyst.

The added amount of the component (E) as the concentration of the catalyst metal element is in the range of preferably 0.5 to 1,000 ppm, more preferably 1 to 500 ppm, and still more preferably 1 to 100 ppm relative to the total mass of the curable silicone composition, although an effective amount thereof according to the curing temperature and curing time desired depending on the use applications is used. If the added amount is less than 0.5 ppm, the addition reaction becomes remarkably slow. If the added amount exceeds 1,000 ppm, the cost increases, which is not economically preferable.

The viscosity (hereinafter referred to as mixing viscosity) of the thermally conductive silicone composition that is a final product containing the components (A) to (E) is not particularly limited. For example, the viscosity is in the range of 50 Pa·s or more and 2,000 Pa·s or less, and more preferably in the range of 60 Pa·s or more and 1,000 Pa·s or less.

For example, the suitable viscosity before curing is in the range of 50 Pa·s or more and 550 Pa·s or less in terms of application workability (dispensing properties) and filling properties of the thermally conductive filler. Furthermore, the resilience score of the gap filler is preferably 10% or more, for example.

Herein, the resilience score refers to a value measured by the following method. Initially, a columnar cured product is produced by pouring the thermally conductive silicone composition into a columnar press mold having a diameter of 30 mm and a height of 6 mm and then curing the composition at 100° C. for 60 minutes. Subsequently, this columnar specimen is compressed to a thickness of 3 mm by a compression jig, left to stand for two hours, and taken out from the jig. Lastly, the thickness of the specimen is measured immediately and 30 minutes after removal from the jig. The resilience score is calculated by the following expression.

Resilience score=(Initial thickness−Thickness 30 minutes after removal from compression jig)/(Initial thickness−Thickness immediately after removal from compression jig)×100(%)

In the curable silicone composition containing the thermally conductive filler of the present invention, as an additional optional component other than the aforementioned components (A) to (E), a conventionally known additive for use in a silicone rubber or gel can be used as long as the object of the present invention is not impaired. Examples of such additives include an organosilicon compound or an organosiloxane (also referred to as a silane coupling agent) that produces silanols by hydrolysis, a cross-linking agent, a condensation catalyst, an adhesive imparting agent, a pigment, a dye, a curing inhibitor, a heat-resistance imparting agent, a flame retardant, an antistatic agent, a conductivity imparting agent, an airtightness improving agent, a radiation shielding agent, an electromagnetic wave shielding agent, a preservative, a stabilizer, an organic solvent, a plasticizer, a fungicide, an organopolysiloxane which contains one hydrogen atom or alkenyl group bonded to a silicon atom within one molecule and which contains no other functional groups, and a non-functional organopolysiloxane containing neither a hydrogen atom nor an alkenyl group bonded to a silicon atom. As these optional components, one type thereof may be used alone, or two or more types thereof may be used in combination as appropriate.

Examples of the silane coupling agent include an organosilicon compound and an organosiloxane having an organic group such as an epoxy group, an alkyl group, or an aryl group and a silicon atom-bonded alkoxy group within one molecule. An example of the silane coupling agent is a silane compound such as octyltrimethoxysilane, octyltriethoxysilane, decyltrimethoxysilane, decyltriethoxysilane, dodecyltrimethoxysilane, or dodecyltriethoxysilane. The silane compound may be a compound having no SiH group. One type thereof may be used alone, or two or more types thereof may be used in combination as appropriate. When the surface of the thermally conductive filler is treated with the silane coupling agent, the affinity with the silicone polymer can be improved, the viscosity of the composition can be decreased, and the filling properties of the filler can be improved. Therefore, when a larger amount of filler is added, thermal conductivity can be improved.

A silanol produced by hydrolysis can react with and bond with a condensable group (for example, a hydroxyl group, an alkoxy group, an acid group, or the like) present on the surface of a metal substrate or an organic resin substrate. The silanol and the condensable group undergo a reaction with and are bonded to each other by the catalytic effect of the condensation catalyst described later, thereby progressing the adhesion of the curable silicone composition to various substrates.

As the amount of the silane coupling agent added relative to that of the filler, an effective amount according to curing temperature or curing time desired depending on the use applications is used. A general optimum amount is usually 0.5 to 2 wt % relative to the amount of the thermally conductive filler. A standard of a required amount is calculated by the following expression. The silane-coupling agent may be added in an amount one to three times the standard of the required amount.

Required amount (g) of silane coupling agent=Weight (g) of filler×Specific surface area (m²/g)/minimal covering area specific to silane coupling agent (m²/g)

The cross-linking agent is an organohydrogenpolysiloxane that can undergo an addition reaction with an alkenyl group to form a cured product and can have at least three or more SiH groups within one molecule. The cross-linking agent in the present invention is preferably an organohydrogenpolysiloxane having five or more SiH groups. The cross-linking agent may be an organohydrogenpolysiloxane having 10 or more and 15 or less SiH groups. The organohydrogenpolysiloxane that is the cross-linking agent has at least one SiH group bonded to the side chain. The number of SiH groups at a molecular chain terminal may be zero or more and two or less, and preferably two in terms of cost. The molecular structure of the organohydrogenpolysiloxane may be any of linear, cyclic, branched, and three-dimensional network structures. The position of the silicon atom to which a hydrogen atom is bonded is not particularly limited. Such a silicon atom may be at a molecular chain terminal, at a non-terminal molecular chain site (in the middle of the molecular chain), or at a side chain. Other conditions, the type of the organic group, the bonding position thereof, the degree of polymerization, structure, and the like in the organohydrogenpolysiloxane serving as the cross-linking agent are not particularly limited. Two or more types of organohydrogenpolysiloxanes may be used.

As necessary, a condensation catalyst may be used together with the silane coupling agent described above. As the condensation catalyst, a compound of a metal selected from magnesium, aluminum, titanium, chromium, iron, cobalt, nickel, copper, zinc, zirconium, tungsten, and bismuth can be used. Preferable examples of the condensation catalysts include metal compounds such as organic acid salts, alkoxides, and chelate compounds, of trivalent aluminum, trivalent iron, trivalent cobalt, divalent zinc, tetravalent zirconium, and trivalent bismuth. Specific examples thereof include an organic acid such as octylic acid, lauric acid, and stearic acid, an alkoxide such as a propoxide and a butoxide, and a multidentate ligand chelating compound such as catechol, crown ether, a polyvalent carboxylic acid, hydroxy acid, diketone, and keto acid. Here, a plurality of types of ligands may be bonded to one metal. In particular, a compound of zirconium, aluminum, or iron, which is likely to give stable curability even when the addition and use conditions are somewhat different, is preferred. In addition, examples of the more desirable compounds include a butoxide of zirconium and a trivalent chelate compound of aluminum or iron including multidentate ligands such as a malonic acid ester, an acetoacetic acid ester, an acetylacetone, or a substituted derivative thereof. In the case of a trivalent aluminum or iron metal compound, an organic acid having 5 to 20 carbon atoms, such as octylic acid, may be preferably used. The polydentate ligand and the organic acid may be bonded to one metal, and the resulting structure may also be adopted.

Examples of the aforementioned substituted derivative include those in which a hydrogen atom contained in the compound described above is substituted with an alkyl group such as a methyl group or an ethyl group, an alkenyl group such as a vinyl group or an allyl group, an aryl group such as a phenyl group, a halogen atom such as a chlorine atom or a fluorine atom, a hydroxyl group, a fluoroalkyl group, an ester group-containing group, an ether-containing group, a ketone-containing group, an amino group-containing group, an amide group-containing group, a carboxylic acid-containing group, a nitrile group-containing group, an epoxy group-containing group, or the like. Furthermore, specific examples thereof include 2,2,6,6-tetramethyl-3,5-heptanedione and hexafluoropentanedione.

Examples of the pigment include titanium oxide, alumina silicic acid, iron oxide, zinc oxide, calcium carbonate, carbon black, a rare earth oxide, chromium oxide, a cobalt pigment, ultramarine blue, cerium silanolate, aluminum oxide, aluminum hydroxide, titanium yellow, barium sulfate, precipitated barium sulfate, and mixtures thereof.

The added amount of the pigment is preferably in the range of 0.001% to 5% relative to the total mass of the thermally conductive silicone composition although an effective amount thereof according to the curing temperature and curing time desired depending on the use applications is used. The amount of the pigment is preferably in the range of 0.01% to 2%, and more preferably 0.05% to 18. If the added amount is less than 0.001%, the resulting composition is insufficiently colored, so it is difficult to visually distinguish the first liquid from the second liquid. On the other hand, if the added amount exceeds 5%, the cost will increase, which is not economically preferable.

The curing inhibitor has an ability of adjusting the curing rate of the addition reaction, and any curing inhibitor conventionally known in the art can be used as the compound having a curing suppressing effect. Examples thereof include an acetylene-based compound, hydrazines, triazoles, phosphines, and mercaptans. Specific examples of such compounds include a phosphorus-containing compound such as triphenylphosphine, a nitrogen-containing compound such as tributylamine, tetramethylethylenediamine, and benzotriazole, a sulfur-containing compound, an acetylene-based compound, a compound containing two or more alkenyl groups, a hydroperoxy compound, a maleic acid derivative, and silane and a silicone compound having an amino group.

The added amount of the curing inhibitor is preferably in the range of 0.1 parts by mass to 15 parts by mass relative to 100 parts by mass of the total amount of the components (A) and (B), although an effective amount thereof depending on the curing temperature and curing time desired depending on the use applications is used. The added amount is preferably in the range of 0.2 parts by mass to 10 parts by mass, and more preferably in the range of 0.5 parts by mass to 5 parts by mass. If the amount is less than 0.1 parts by mass, the addition reaction becomes remarkably accelerated, and the curing reaction proceeds during coating, which may deteriorate the workability. On the other hand, if the amount exceeds 10 parts by mass, the addition reaction becomes slow, so a pump-out phenomenon may occur.

Specific examples of the curing inhibitors include various “ene-yne” systems such as 3-methyl-3-pentene-1-yne and 3,5-dimethyl-3-hexene-1-yne; an acetylenic alcohol such as 3,5-dimethyl-1-hexin-3-ol, 1-ethynyl-1-cyclohexanol, and 2-phenyl-3-butyn-2-ol; well-known maleates and fumarates such as a dialkyl maleate, a dialkenyl maleate, a dialkoxyalkyl maleate, a dialkyl fumarate, a dialkenyl fumarate, and a dialkoxyalkyl fumarate; and those containing cyclovinylsiloxane.

Examples of the heat-resistance imparting agent include cerium hydroxide, cerium oxide, iron oxide, fumed titanium dioxide, and mixtures thereof.

As the airtightness improving agent, any agent may be used as long as it has an effect of reducing the air permeability of the cured product, and any organic or inorganic substance may be used. Specific examples thereof include a urethane, a polyvinyl alcohol, a polyisobutylene, an isobutylene-isoprene copolymer, talc having a plate-like shape, mica, glass flakes, boehmite, powders of various metal foils and metal oxides, and mixtures thereof.

The thermally conductive silicone composition according to the present invention may not contain an organosilicon compound having one or more alkenyl groups and one or more alkoxy groups bonded to silicon atoms within one molecule. When a compound having an alkenyl group and an alkoxy group bonded to a silicon atom within one molecule is contained, the compound acts as a component for bonding the substrate to the gap filler. The composition according to the present invention that does not contain such a component can suppress a phenomenon where the substrate is deformed or cracked during application of unintended impact to the substrate. When the substrate is a resin film (PET film, etc.) with which the surface of a battery is coated, the composition according to the present invention that does not contain such a component can suppress a phenomenon where the substrate is separated from the battery. This is based on the properties of the composition according to the present invention in which the gap filler is in close contact with the substrate, but is not attached to the substrate.

The composition according to the present invention is a thermally conductive silicone composition that is applied in a liquid state to a substrate. That is, the composition is a liquid having an initial viscosity, at 25° C., of 80 mPa·s or more and 500 mPa·s or less, and forms a non-flowable reactant (gap filler) within 120 minutes after being applied to a substrate.

The liquid silicone composition having a viscosity within the aforementioned range can be extruded from a cartridge, a ribbon, or a container such as a dispenser, a syringe or a tube, and applied to a substrate. It is preferable to apply the composition to a substrate using a dispenser with an L-shaped nozzle/needle or the like.

Here, the substrate refers to a heat dissipation portion (heat dissipation body) and a heat generating portion (heat generating body).

In the present invention, the substrate may be made of one or more materials selected from a glass, a metal, a ceramics, and a resin.

Preferable examples of metal substrates with which the thermally conductive silicone composition of the present invention is in close contact after curing include metal substrates of a metal selected from the group consisting of aluminum, magnesium, iron, nickel, titanium, stainless steel, copper, lead, zinc, molybdenum, silicon, and alloys of these metals.

Preferable examples of ceramic substrates with which the thermally conductive silicone composition of the present invention is in close contact after curing include an oxide, a carbide, and a nitride such as aluminum oxide, aluminum nitride, alumina zirconia, zirconium oxide, zinc oxide, barium titanate, lead zirconate titanate, beryllium oxide, silicon nitride, and silicon carbide.

Preferable examples of resin substrates with which the thermally conductive silicone composition of the present invention is in close contact after curing include resin substrates of a resin selected from the group consisting of a polyester, an epoxy, a polyamide, a polyimide, an ester, a polyacrylamide, an acrylonitrile-butadiene-styrene (ABS), a styrene, a polypropylene, a polyacetal, an acrylic resin, a polycarbonate (PC), a polyethylene terephthalate (PET), a polybutylene terephthalate (PBT), a polyetheretherketone (PEEK), a polymethylmethacrylate (PMMA), and a silicone resin.

When the thermally conductive member obtained by curing the thermally conductive silicone composition of the present invention is a gap filler for battery units, a casing for such battery units, which serves as the substrate to be an adherend, has a substrate surface with an iron surface partially coated with a cationic electrodeposition coating. When the member is a heat sink, such a heat sink may have an aluminum surface.

In the target products to which the silicone composition is applied, the heat generating portion may be disposed so as to sandwich the silicone composition after the silicone composition is applied to the heat dissipating portion, the heat dissipation portion may be disposed so as to sandwich the silicone composition after the silicone composition is applied to the heat generating portion, or the silicone composition may be injected into a gap created between the heat generating portion and the heat dissipation portion.

In the composition described above, the components (A) and (B) undergo a crosslinking reaction in the presence of the addition reaction catalyst (E) to give a cured product (gap filler). The composition should have a thermal conductivity of 1 or more, and may preferably be 2 or more. The specific gravity of the composition should be 1.5 or more and 10 or less. Since having reduced weight tends to be important for a member including a substrate to which the thermally conductive silicone composition is applied (e.g., an electronic device, a battery, or the like), the specific gravity of the composition is preferably 5.0 or less, and more preferably 3.0 or less.

Furthermore, the aforementioned composition preferably has certain insulation properties, and specifically, the volume resistivity thereof is preferably 10¹⁰ (Ω·cm) or higher.

The thermally conductive silicone composition according to the present invention is an addition-curable composition and may be a one-component composition or a two-component composition. The one-component composition can have an improved storage property when the composition is appropriately designed to be cured by heat or moisture.

In the case of a two-component composition, it becomes possible to further improve storage stability without these contrivances, and it is easy to obtain a composition that cures at room temperature (e.g., 25° C.).

In that case, the silicone composition according to the present invention can be dispensed into the first liquid and the second liquid, for example as follows.

The first liquid does not contain component (B) and contains component (E), and the second liquid contains component (B) and does not contain component (E).

For example, the first liquid contains:
the component (A) that is a diorganopolysiloxane having an alkenyl group bonded to a silicon atom, with a viscosity, at 25° C., of 10 mPa·s or more and 1,000,000 mPa·s or less;
the component (C) that is a thermally conductive filler;
the component (D) that is a silicone resin having at least one alkenyl group within one molecule, with a number-average molecular weight of 1,000 or more; and
the component (E) that is an addition reaction catalyst, and
does not contain the component (B) that is a diorganopolysiloxane having a hydrogen atom bonded to a silicon atom, with a viscosity, at 25° C., of 10 mPa·s or more and 1,000,000 mPa·s or less.

The second liquid contains:
the component (A) that is a diorganopolysiloxane having an alkenyl group bonded to a silicon atom, with a viscosity, at 25° C., of 10 mPa·s or more and 1,000,000 mPa·s or less;
the component (B) that is a diorganopolysiloxane having a hydrogen atom bonded to a silicon atom, with a viscosity, at 25° C., of 10 mPa·s or more and 1,000,000 mPa·s or less;
the component (C) that is a thermally conductive filler; and
the component (D) that is a silicone resin having at least one alkenyl group within one molecule, with a number-average molecular weight of 1,000 or more; and
does not contain the component (E) that is an addition reaction catalyst.

The first liquid and the second liquid may optionally contain a cross-linking agent, a coupling agent, a curing inhibitor, a pigment, and the like. The coupling agent and the curing inhibitor may be added to either the first liquid or the second liquid, or may be added to both of them. The mixing procedure of the coupling agent is not particularly limited, but is preferably added before or simultaneously with the addition of the filler of the component (C). The cross-linking agent is preferably added to the second liquid which does not contain a platinum catalyst. The mixing procedure of the cross-linking agent is not particularly limited, but is preferably added simultaneously with the addition of the diorganopolysiloxane. The pigment is preferably added to either the first liquid or the second liquid for visually identifying the first liquid and the second liquid. The mixing procedure of the pigment is not particularly limited, but is preferably simultaneously with, or subsequent to, the addition of the filler of the component (C).

In order to dispense and store the composition as the first liquid and the second liquid, each of these components may be stored in an organic solvent such as toluene, xylene, hexane, or white spirit, or a mixture thereof. Alternatively, the different components may be emulsified using an emulsifying agent and stored as an aqueous emulsion. In particular, in order to prevent problems such as risk of fire due to volatilization of an organic solvent, deterioration of a working environment, and air pollution, it may be preferable to use a solvent-free system composition or an emulsion that is emulsified by an emulsifying agent.

The present invention is also a method for improving a resiliency of a cured product obtained by curing a thermally conductive silicone composition, the method including: adding the component (D) that is a silicone resin having a number-average molecular weight of 1,000 or more to a thermally conductive silicone composition that contains the component (A) that is a diorganopolysiloxane having an alkenyl group bonded to a silicon atom, with a viscosity, at 25° C., of 10 mPa·s or more and 1,000,000 mPa·s or less, the component (B) that is a diorganopolysiloxane having a hydrogen atom bonded to a silicon atom, with a viscosity, at 25° C., of 10 mPa·s or more and 1,000,000 mPa·s or less, the component (C) that is a thermally conductive filler, and the component (E) that is an addition reaction catalyst; applying the resulting thermally conductive silicone composition in a liquid state to a substrate; and curing the thermally conductive silicone composition to obtain the cured product with an improved resiliency.

As a method for producing the thermally conductive

silicone composition according to the present invention, any method known by a person skilled in the art can be used without limitation. For example, the method may include steps of mixing the components (A), (B), and (D), adding the component (C) to the mixture, and mixing the mixture.

An exemplary method for producing the composition includes mixing the components (A), (B) and (D) in advance with a stirrer, or uniformly kneading these components with a high-shear mixer or extruder such as a two-roll mill, a kneader, a pressure kneader, a Ross mixer, a continuous extruder, or the like, to prepare a silicone rubber base, and then adding the component (C) thereto.

The component (E) and other optional components should be ultimately added in the silicone composition and may be mixed with the components (A), (B) and (D), but may also be mixed with the component (C), and may be mixed after mixing the component (C).

A step of warming the component (D) or dissolving the component (D) in advance may be added, if necessary.

Furthermore, the present invention is a method for producing the gap filler. This method includes steps of discharging the thermally conductive silicone composition from a container filled with the thermally conductive silicone composition and applying the thermally conductive silicone composition to a substrate which is at least one or both of a heat generating part and a heat dissipating part. The temperature of the composition during curing after applying the composition to the substrate is not particularly limited, and may be, for example, 15° C. or higher and 60° C. or lower. In order to decrease thermal damage against the substrate, the temperature may be set to a temperature of 15° C. or higher and 40° C. or lower. In a case of a heating-curable composition, the composition may be heated after applying the composition to the substrate, or the composition may be cured using heat dissipated from a heat dissipation member. The temperature during heat-curing may be, for example, 40° C. or higher and 200° C. or lower.

The substrate to which the gap filler is applied is not particularly limited, and examples thereof include resins such as a polyethylene terephthalate (PET), a poly(1,4-butylene terephthalate) (PBT), and a polycarbonate, ceramics, glasses, and metals such as aluminum.

The present invention also provides a gap filler that is obtained by curing the above-described thermally conductive silicone composition and that has an improved resiliency by adding the component (D), wherein the content of the component (C) is 300 parts by mass or more and 2,000 parts by mass or less, and the content of the component (D) is 1 part by mass or more and 10 parts by mass or less, relative to 100 parts by mass of the total amount of the components (A) and (B) in the thermally conductive silicone composition.

The gap filler of the present invention can be applied to electronic devices including a heat generating portion such as a battery. In particular, the gap filler of the present invention can be applied to at least a part of the heat generating portion to exhibit good heat dissipation properties.

### EXAMPLES

The present invention will be specifically described on the basis of Examples, but the present invention is not limited to the following Examples. Tables 1 and 2 show mixing ratios of components in Examples and Comparative Examples, and evaluation results. Numerical values of the mixing ratios shown in Tables 1 and 2 are expressed in part by mass.

### Method for Producing Thermally Conductive Silicone Composition and Cured Product Thereof

A first liquid and a second liquid described in each of Examples and Comparative Examples were weighed at a ratio of 1:1, sufficiently mixed by a stirrer, and then degassed by a vacuum pump, to produce each thermally conductive silicone composition. The thermally conductive silicone compositions were each cured at 23° C. for 24 hours so as to obtain a specimen in accordance with each evaluation item. As a result, each cured product was obtained.

### Method for Measuring Hardness

The first liquid and the second liquid described in each of Examples and Comparative Examples were weighed at a ratio of 1:1, sufficiently mixed by a stirrer, and then degassed by a vacuum pump. The resultant thermally conductive silicone composition was poured into a columnar press mold having a diameter of 30 mm and a height of 6 mm, and then cured at 100° C. for 60 minutes, to obtain each columnar cured product.

An Asker C hardness was measured by a hardness tester (“ASKER CL-150LJ” manufactured by KOBUNSHI KEIKI CO., LTD.) in an environment of 23° C. in accordance with Asker C method in the Japanese Rubber Institute Standard (SRIS 0101).

Specifically, the damper height was adjusted such that the distance between the obtained columnar cured product and an indicator was 15 mm, and the damper falling speed was adjusted such that the time when the indicator reached the surface of a sample was 5 seconds. The maximum value when the indicator collided the sample was defined as a measured value of Asker C hardness. The Asker C hardness was measured three times by the hardness tester, and the average of the measured values was used. In general, as the Asker C hardness is smaller, flexibility is higher.

It is preferable that the Asker C hardness of the cured product fall within the range of 30 or more and 70 or less.

### Method for Measuring Specific Gravity

The first liquid and the second liquid described in each of Examples and Comparative Examples were weighed at a ratio of 1:1, sufficiently mixed by a stirrer, and then degassed by a vacuum pump. The resultant thermally conductive silicone composition was poured into a sheet-shaped press mold having a height of about 10 cm, a width of about 10 cm, and a thickness of 2 mm, and then cured at 100° C. for 60 minutes, to obtain each cured product.

The specific gravity (density) (g/cm³) of the cured product obtained in each of Examples and Comparative Examples was measured in accordance with JIS K6249.

In a case of application in which weight reduction is important, the specific gravity is preferably 3.0 g/cm³ or less.

### Method for Measuring Thermal Conductivity

The first liquid and the second liquid described in each of Examples and Comparative Examples were weighed at a ratio of 1:1, sufficiently mixed by a stirrer, and then degassed by a vacuum pump. The resultant thermally conductive silicone composition was poured into a columnar press mold having a diameter of 30 mm and a height of 6 mm, and then cured at 100° C. for 60 minutes, to obtain each columnar cured product. The thermal conductivity of the cured product was measured by a measurement device (TPS-500 manufactured by Kyoto Electronics Manufacturing Co., Ltd.) on the basis of a hot disc method in accordance with ISO 22007-2. A sensor was disposed between two columnar cured products produced as described above, and the thermal conductivity was measured by the measurement device.

The thermal conductivity is preferably 2.0 W/m·k or more.

### Method for Measuring Mixing Viscosity

The first liquid and the second liquid described in each of Examples and Comparative Examples were weighed at a ratio of 1:1, and sufficiently mixed by a stirrer, and the viscosity of the mixture was measured at 25° C. in accordance with JIS K7117-2. Specifically, the not yet cured thermally conductive silicone composition was placed between parallel plates having a diameter of 25 mm, and the viscosity thereof was measured at a shear rate of 10 (1/s) and a gap of 0.5 mm by Physica MR 301 manufactured by Anton Paar.

It can be said that the coating workability is good if the viscosity is 500 Pa·s or less.

### Method for Measuring Resilience Score

The first liquid and the second liquid described in each of Examples and Comparative Examples were weighed at a ratio of 1:1, sufficiently mixed by a stirrer, and then degassed by a vacuum pump. The resultant thermally conductive silicone composition was poured into a columnar press mold having a diameter of 30 mm and a height of 6 mm and then cured at 100° C. for 60 minutes, to obtain each columnar cured product. This columnar specimen was compressed into 3 mm by a compression jig, left to stand for two hours, and taken out from the jig. The thickness of the specimen was measured immediately and 30 minutes after removal from the jig. The resilience score was calculated by the following expression.

Resilience score=(Initial thickness−Thickness 30 minutes after removal from compression jig)/(Initial thickness−Thickness immediately after removal from compression jig)×100(%)

### Method for Producing Cured Product of Thermally Conductive Silicone Composition

### Example 1

The first liquid and the second liquid were each produced in accordance with the chemical composition shown in fields of Example 1 in Table by the following procedures. The unit of mixing ratio of each component shown in Tables is part by mass.

### First Liquid for Examples 1 and 7

A diorganopolysiloxane having an alkenyl group as the component (A), a silicone resin (organopolysiloxane resin) as the component (D), a platinum-divinyltetramethyldisiloxane complex as the component (E), an n-octyltriethoxysilane as a silane coupling agent of an optional component, A-137 manufactured by Momentive Performance Materials Worldwide LLC, 3-methyl-3-pentene-1-yne as a curing inhibitor, and Stan-Tone 50SP01 Green manufactured by Polyone Corp. as a pigment were each weighed, added together, and kneaded at room temperature for 30 minutes with a planetary mixer.

The component (A) is a linear dimethylpolysiloxane having alkenyl groups only at both terminals, with a viscosity of 120 mPa·s.

The component (D) is an organopolysiloxane resin consisting of an R₃SiO_{1/2} (M) unit and an SiO_{4/2} (Q) unit, known as an MQ resin (MQ resin 804 manufactured by Wacker Chemie AG.) having a number-average molecular weight of about 5,000.

Subsequently, a half amount of the silane coupling agent as the optional component, and respective half amounts of spherical alumina having an average particle diameter of 90 μm and amorphous alumina having an average particle diameter of 4 μm as the thermally conductive filler of the component (C) were added and kneaded for 15 minutes at room temperature with a planetary mixer.

Spherical alumina DAM-90 (average particle diameter of 90 μm) manufactured by Denka Co., Ltd. was used as the spherical alumina.

Fine-grained alumina SA34 (average particle diameter of 4 μm) manufactured by Nippon Light Metal Co., Ltd. was used as the amorphous alumina.

After that, a half amount of the silane coupling agent, and respective half amounts of the spherical thermally conductive filler and the amorphous thermally conductive filler as the component (C) were added, and kneaded for 15 minutes at room temperature with a planetary mixer to prepare a first liquid.

### Second Liquid for Examples 1 and 7

A diorganopolysiloxane, having the same alkenyl group as that for the first liquid, as the component (A), a linear diorganopolysiloxane having a viscosity of 100 mPa·s with two hydrogen atoms at both terminals as the component (B), the same MQ resin as that for the first liquid as the component (D), and a cross-linking agent and a silane coupling agent as optional components were each weighed, added together, and kneaded for 30 minutes at room temperature with a planetary mixer.

The cross-linking agent as the optional component is a dimethylpolysiloxane having hydrogen atoms bonded to the silicon atoms only at the side chains, with a viscosity of 200 mPa·s.

Subsequently, a half amount of the silane coupling agent as the optional component, and respective half amounts of the spherical alumina having an average particle diameter of 90 μm and the amorphous alumina having an average particle diameter of 4 μm as the thermally conductive filler of the component (C) the same as those for the first liquid were added and kneaded for 15 minutes at room temperature with a planetary mixer.

After that, a half amount of the silane coupling agent, and respective half amounts of the spherical thermally conductive filler and the amorphous thermally conductive filler as the component (C) the same as those for the first liquid were added, and kneaded for 15 minutes at room temperature with a planetary mixer to prepare a second liquid.

### Examples 2, 3, and 4

A first liquid and a second liquid were prepared in the same manner as that in Example 1 except that the type of the silicone resin (organopolysiloxane resin) was changed.

The organopolysiloxane resin of the component (D) described in Example 2 is an organopolysiloxane resin consisting of an R₃SiO_{1/2} (M) unit and an SiO_{4/2} (Q) unit, known as an MQ resin, having a number-average molecular weight of about 3,000. The organopolysiloxane resin contains 1% to 20% alkenyl groups.

The organopolysiloxane resin of the component (D) described in Example 3 is an organopolysiloxane resin consisting of an R₃SiO_{1/2} (M) unit and an SiO_{4/2} (Q) unit, known as an MQ resin, having a number-average molecular weight of about 2,000. The organopolysiloxane resin contains 1% to 20% alkenyl groups.

The organopolysiloxane resin of the component (D) described in Example 4 is an organopolysiloxane resin consisting of an R₂SiO_{2/2} (D) unit and an RSiO_{3/2} (T) unit, known as a DT resin, having a number-average molecular weight of about 6,000. The organopolysiloxane resin contains no alkenyl group.

### Examples 5 and 6

A first liquid and a second liquid were prepared in the same manner as that in Example 1 except that the added amount of the spherical thermally conductive filler with a large particle diameter and the added amount of the MQ resin were changed.

### Example 8

A first liquid and a second liquid were prepared in the same manner as that in Example 1 except that spherical alumina having an average particle diameter of 40 μm was used as the spherical thermally conductive filler.

Spherical alumina DAM-40 (average particle diameter of 40 μm) manufactured by Denka Co., Ltd. was used as the spherical alumina.

### Example 9

A first liquid and a second liquid were prepared in the same manner as that in Example 1 except that spherical thermally conductive alumina having an average particle diameter of 5 μm was used instead of the amorphous thermally conductive alumina.

Spherical alumina DAM-5 (average particle diameter of 5 μm) manufactured by Denka Co., Ltd. was used as the spherical alumina.

### Examples 10, 11, and 12

A first liquid and a second liquid were prepared in the same manner as that in Example 1 except that a diorganopolysiloxane having an alkenyl group with a viscosity of 1,000 mPa·s was used as the components (A) for Examples 2, 3, and 4.

Specifically, the component (A) is a linear dimethylpolysiloxane having an alkenyl group only on the side chain with a viscosity of 1,000 mPa·s.

### Example 13

A first liquid and a second liquid were prepared in the same manner as that in Example 12 except that the added amount of the MQ resin in Example 12 was changed to 2 parts by mass relative to 100 parts by mass of the total amount of the components (A) and (B).

### Example 14

A first liquid and a second liquid were prepared in the same manner as that in Example 3 except that the added amount of the MQ resin in Example 3 was changed to 10 parts by mass relative to 100 parts by mass of the total amount of the components (A) and (B).

### Example 15

A first liquid and a second liquid were prepared in the same manner as that in Example 12 except that the added amount of the MQ resin in Example 12 was changed to 10 parts by mass relative to 100 parts by mass of the total amount of the components (A) and (B).

### Example 16

A first liquid and a second liquid were prepared in the same manner as that in Example 3 except that the added amount of the MQ resin in Example 3 was changed to 12 parts by mass relative to 100 parts by mass of the total amount of the components (A) and (B).

### Example 17

A first liquid and a second liquid were prepared in the same manner as that in Example 3 except that the added amount of the MQ resin in Example 3 was changed to 1.5 parts by mass relative to 100 parts by mass of the total amount of the components (A) and (B).

### Comparative Example 1

A first liquid and a second liquid were prepared in the same manner as that in Example 1 except that no silicone resin as the component (D) was contained.

### Comparative Example 2

A first liquid and a second liquid were prepared in the same manner as that in Example 1 except that the added amount of the silicone resin as the component (D) was changed.

### Comparative Example 3

A first liquid and a second liquid were prepared in the same manner as that in Comparative Example 1 except that the added amount of the cross-linking agent was changed.

### Comparative Example 4

A first liquid and a second liquid were prepared in the same manner as in those Example 1 except that the added amount of the silicone resin as the component (D) was changed.

### Comparative Example 5

A first liquid and a second liquid were prepared in the same manner as that in Example 1 except that the silicone resin of the component (D) was changed to a silicone resin having no alkenyl group. Specifically, the organopolysiloxane resin used in Comparative Example 5 is an organopolysiloxane resin consisting of an R₃SiO_{1/2} (M) unit and an SiO_{4/2} (Q) unit, known as an MQ resin, having a number-average molecular weight of about 7,900.

The evaluation results are as shown in Tables 1 and 2.

In Examples 1 to 4, 4 parts by mass of the MQ resin or the DT resin was added as the silicone resin of the component (D). The resilience score was favorable at 10% or more, the viscosity was sufficiently low at 200 Pa·s or less, and dispensing properties were favorable.

In Example 5, the added amount of the filler was smaller than that in Example 1 by 250 parts by mass in total, and the added amount of MQ resin was decreased to 1 part by mass. Thermal conductivity was slightly decreased, but the resilience score of 10% was secured and the viscosity was favorable at 500 Pa·s or less.

In Example 6, the amount of the MQ resin was larger than that in Example 5. The resilience score was 30%, and a noticeable effect was obtained.

In Example 7, the added amount of the filler was larger than that in Example 6 by 350 parts by mass. The resilience score was decreased to 10%, but the thermal conductivity was high at 3.3 W/m·K.

In Example 8, the particle diameter of the spherical thermally conductive filler in Example 1 was changed to 40 μm. The viscosity and hardness were slightly increased, but the resilience score was favorable at 15%.

In Example 9, the amorphous alumina was changed to the spherical alumina. The viscosity and hardness were slightly decreased, but the resilience score was favorable at 15%.

In Examples 10 to 13, the viscosity of the component (A) was changed from 120 mPa·s to 1,000 mPa·s. The viscosity was increased, but the resilience score was 19% or more.

In Example 14, the viscosity of the component (A) was 120 mPa·s, and 10 parts by mass of the MQ resin was added. The viscosity and hardness were increased, but the resilience score was favorable at 20%.

In Example 15, the viscosity of the component (A) was 1,000 mPa·s, and 10 parts by mass of the MQ resin was added. The viscosity and hardness were further increased, but the resilience score was further favorable at 25%.

In Example 16, the viscosity of the component (A) was 120 mPa·s, and 12 parts by mass of the MQ resin was added. The viscosity and hardness were further increased, but the resilience score was further favorable at 25%.

In Example 17, the viscosity of the component (A) was 120 mPa·s, and 1.5 parts by mass of MQ resin was added. The multiplicative product of the amount of the component (D) contained in parts by mass with the number-average molecular weight of the component (D) was 3,000 or less, but the resilience score was 11%.

In Comparative Example 1, an organopolysiloxane resin was not added, but the resilience score was 0%. That is, when the crushed gap filler is temporarily separated from the substrate, adhesion is impaired, and heat dissipation properties are possibly impaired.

Comparative Example 2 is an attempt to decrease the added amount of the organopolysiloxane resin to the utmost limit and suppress an increase in viscosity. However, the resilience score was low at 5%, and the resiliency could not be deemed to be sufficient.

Comparative Example 3 is an attempt to increase crosslink density without mixing an organopolysiloxane resin in order to improve resiliency. The hardness was 90, and the flexibility of the gap filler was decreased. This was not preferred in terms of followability and stress relaxation in conditions where vibration occurs.

In Comparative Example 4, the added amount of the organopolysiloxane resin was small, and the multiplicative product of the amount of the resin contained in parts by mass with the number-average molecular weight of the resin was 3,000 or less. The resilience score was low at 5%, and the resiliency was not deemed to be sufficient.

In Comparative Example 5, an organopolysiloxane resin having no alkenyl group was added. The resilience score was low at 5%, and the resiliency was not deemed to be sufficient.

TABLE 1

| | | | | Example | | | | |
|---|---|---|---|---|---|---|---|---|
| | | | | 1 | 2 | 3 | 4 | 5 |
| First | S [symbol] V [symbol] Polymer | Low Viscosity (120 Pa · s) | (A) - 1 | 100.0 | 100.0 | 100.0 | 100.0 | 100.0 |
| Liquid | | High Viscosity (1000 Pa · s) | (A) - 2 | | | | | |
| | Filler | Amorphous Alumina (4 μm) | (C) - 1 | 350.0 | 350.0 | 350.0 | 350.0 | 300.0 |
| | | Spherical Alumina with small | (C) - 2 | | | | | |
| | | particle diameter (5 μm) | | | | | | |
| | | Spherical Alumina with medium | (C) - 3 | | | | | |
| | | particle diameter (40 μm) | | | | | | |
| | | Spherical Alumina with large | (C) - 4 | 600.0 | 600.0 | 600.0 | 600.0 | 400.0 |
| | | particle diameter (90 μm) | | | | | | |
| | Resin | High molecular-weight MQ | (D) - 1 | 4.0 | | | | 1.0 |
| | | Middle molecular-weight MQ | (D) - 2 | | 4.0 | | | |
| | | Low molecular-weight MQ | (D) - 3 | | | 4.0 | | |
| | | High molecular-weight DT | (D) - 4 | | | | 4.0 | |
| | | MQ (No [symbol] ) | (D) - [symbol] | | | | | |
| | Addition Reaction Catalyst | | (E) | 2.0 | 2.0 | 2.0 | 2.0 | 2.0 |
| | Coupling Agent | | | 1.0 | 1.0 | 1.0 | 1.0 | 1.0 |
| | Curing Inhibitor | | | 2.0 | 2.0 | 2.0 | 2.0 | 2.0 |
| | Pigment | | | 1.0 | 1.0 | 1.0 | 1.0 | 1.0 |
| Second | S [symbol] V [symbol] Polymer | | (A) - 1 | 40 | 40 | 40 | 40 | 40 |
| Liquid | S [symbol] H Polymer | | (B) | 60 | 60 | 60 | 60 | 60 |
| | Filler | Amorphous Alumina (4 μm) | (C) - 1 | 350.0 | 350.0 | 350.0 | 350.0 | 300.0 |
| | | Spherical Alumina with small | (C) - 2 | | | | | |
| | | particle diameter (5 μm) | | | | | | |
| | | Spherical Alumina with medium | (C) - 3 | | | | | |
| | | particle diameter (40 μm) | | | | | | |
| | | Spherical Alumina with large | (C) - 4 | 600.0 | 600.0 | 600.0 | 600.0 | 400.0 |
| | | particle diameter (90 μm) | | | | | | |
| | Resin | High molecular-weight MQ | (D) - 1 | 4.0 | | | | 1.0 |
| | | Middle molecular-weight MQ | (D) - 2 | | 4.0 | | | |
| | | Low molecular-weight MQ | (D) - 3 | | | 4.0 | | |
| | | High molecular-weight DT | (D) - 4 | | | | 4.0 | |
| | | MQ (No [symbol] ) | (D) - [symbol] | | | | | |
| | Cross-Linking Agent | | | 1.0 | 1.0 | 1.0 | 1.0 | 1.0 |
| | Coupling Agent | | | 1.0 | 1.0 | 1.0 | 1.0 | 1.0 |
| | Product of Amount of Component (D) Contained in Parts by Mass with Number- | | | 0 | 0 | 0 | 0 | 0 |
| | Average Molecular Weight of Component (D) | | | | | | | |
| Results | | | Reference Range | | | | | |
| | Hardness (AKSER-C) | | 30-70 | 40 | 40 | 40 | 40 | 35 |
| | Specific Gravity | | 2.8-3.0 | 2.88 | 2.88 | 2.88 | 2.88 | 2.80 |
| | Thermal Conductivity | | 2.5 W/m · k [symbol] or more | 3.1 | 3.1 | 3.1 | 3.1 | 2.5 |
| | Mixing Viscosity( [symbol] ) | | 80-500 Pa · s | 150 | 120 | 100 | 180 | 135 |
| | Resilience Score | | 10% or more | 18% | 15% | 13% | 15% | 10% |

| | | | | Example | | | | |
|---|---|---|---|---|---|---|---|---|
| | | | | 6 | 7 | 8 | 9 | 10 |
| First | S [symbol] V [symbol] Polymer | Low Viscosity (120 Pa · s) | (A) - 1 | 100.0 | 100.0 | 100.0 | 100.0 | |
| Liquid | | High Viscosity (1000 Pa · s) | (A) - 2 | | | | | 100.0 |
| | Filler | Amorphous Alumina (4 μm) | (C) - 1 | 300.0 | 350.0 | 350.0 | | 350.0 |
| | | Spherical Alumina with small | (C) - 2 | | | | 350.0 | |
| | | particle diameter (5 μm) | | | | | | |
| | | Spherical Alumina with medium | (C) - 3 | | | 600.0 | | |
| | | particle diameter (40 μm) | | | | | | |
| | | Spherical Alumina with large | (C) - 4 | 400.0 | 700.0 | | 600.0 | 600.0 |
| | | particle diameter (90 μm) | | | | | | |
| | Resin | High molecular-weight MQ | (D) - 1 | 2.0 | 2.0 | 2.0 | 2.0 | 4.0 |
| | | Middle molecular-weight MQ | (D) - 2 | | | | | |
| | | Low molecular-weight MQ | (D) - 3 | | | | | |
| | | High molecular-weight DT | (D) - 4 | | | | | |
| | | MQ (No [symbol] ) | (D) - [symbol] | | | | | |
| | Addition Reaction Catalyst | | (E) | 2.0 | 2.0 | 2.0 | 2.0 | 2.0 |
| | Coupling Agent | | | 1.0 | 1.0 | 1.0 | 1.0 | 1.0 |
| | Curing Inhibitor | | | 2.0 | 2.0 | 2.0 | 2.0 | 2.0 |
| | Pigment | | | 1.0 | 1.0 | 1.0 | 1.0 | 1.0 |
| Second | S [symbol] V [symbol] Polymer | | (A) - 1 | 40 | 40 | 40 | 40 | 40 |
| Liquid | S [symbol] H Polymer | | (B) | 60 | 60 | 60 | 60 | 60 |
| | Filler | Amorphous Alumina (4 μm) | (C) - 1 | 300.0 | 350.0 | 350.0 | | 350.0 |
| | | Spherical Alumina with small | (C) - 2 | | | | 350.0 | |
| | | particle diameter (5 μm) | | | | | | |
| | | Spherical Alumina with medium | (C) - 3 | | | 600.0 | | |
| | | particle diameter (40 μm) | | | | | | |
| | | Spherical Alumina with large | (C) - 4 | 400.0 | 700.0 | | 600.0 | 600.0 |
| | | particle diameter (90 μm) | | | | | | |
| | Resin | High molecular-weight MQ | (D) - 1 | 2.0 | 2.0 | 2.0 | 2.0 | 4.0 |
| | | Middle molecular-weight MQ | (D) - 2 | | | | | |
| | | Low molecular-weight MQ | (D) - 3 | | | | | |
| | | High molecular-weight DT | (D) - 4 | | | | | |
| | | MQ (No [symbol] ) | (D) - [symbol] | | | | | |
| | Cross-Linking Agent | | | 1.0 | 1.0 | 1.0 | 1.0 | 1.0 |
| | Coupling Agent | | | 1.0 | 1.0 | 1.0 | 1.0 | 1.0 |
| | Product of Amount of Component (D) Contained in Parts by Mass with Number- | | | 0 | 0 | 0 | 0 | 0 |
| | Average Molecular Weight of Component (D) | | | | | | | |
| Results | | | Reference Range | | | | | |
| | Hardness (AKSER-C) | | 30-70 | 30 | 40 | 60 | 35 | 60 |
| | Specific Gravity | | 2.8-3.0 | 2.80 | 2.90 | 2.87 | 2.87 | 2.68 |
| | Thermal Conductivity | | 2.5 W/m · k [symbol] or more | 2.5 | 3.3 | 2.8 | 3.2 | 3.1 |
| | Mixing Viscosity( [symbol] ) | | 80-500 Pa · s | 100 | 170 | 300 | 100 | 4 [symbol] 0 |
| | Resilience Score | | 10% or more | 30% | 10% | 15% | 15% | 19% |

[symbol]

indicates data missing or illegible when filed

TABLE 2

| | | | | Example | | | | | | | [symbol] | | | | |
|---|---|---|---|---|---|---|---|---|---|---|---|---|---|---|---|
| | | | | 11 | 12 | 13 | 14 | 15 | 16 | 17 | 1 | 2 | 3 | 4 | 5 |
| [symbol] | [symbol] | [symbol] | [symbol] | | | | [symbol] | | [symbol] | [symbol] | [symbol] | [symbol] | [symbol] | [symbol] | [symbol] |
| [symbol] | | [symbol] | [symbol] | [symbol] | [symbol] | [symbol] | | [symbol] | | | | | | | |
| | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| | | [symbol] | [symbol] | | | | | | | | | | | | |
| | | [symbol] | | | | | | | | | | | | | |
| | | [symbol] | [symbol] | | | | | | | | | | | | |
| | | [symbol] | | | | | | | | | | | | | |
| | | [symbol] | | | | | | | | | | | | | |
| | | [symbol] | [symbol] | [symbol] | [symbol] | [symbol] | [symbol] | [symbol] | [symbol] | [symbol] | [symbol] | [symbol] | [symbol] | [symbol] | [symbol] |
| | | [symbol] | | | | | | | | | | | | | |
| | [symbol] | [symbol] | [symbol] | | | | | | | | | | | [symbol] | |
| | | [symbol] | [symbol] | [symbol] | | | | | | | | | | | |
| | | [symbol] | [symbol] | | [symbol] | [symbol] | [symbol] | [symbol] | [symbol] | [symbol] | | [symbol] | | | |
| | | [symbol] | [symbol] | | | | | | | | | | | | |
| | | [symbol] | [symbol] | | | | | | | | | | | | [symbol] |
| | [symbol] | | [symbol] | [symbol] | [symbol] | [symbol] | [symbol] | [symbol] | [symbol] | [symbol] | [symbol] | [symbol] | [symbol] | [symbol] | [symbol] |
| | [symbol] | | | [symbol] | [symbol] | [symbol] | [symbol] | [symbol] | [symbol] | [symbol] | [symbol] | [symbol] | [symbol] | [symbol] | [symbol] |
| | [symbol] | | | [symbol] | [symbol] | [symbol] | [symbol] | [symbol] | [symbol] | [symbol] | [symbol] | [symbol] | [symbol] | [symbol] | [symbol] |
| | [symbol] | | | [symbol] | [symbol] | [symbol] | [symbol] | [symbol] | [symbol] | [symbol] | [symbol] | [symbol] | [symbol] | [symbol] | [symbol] |
| [symbol] | [symbol] | | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | | [symbol] | [symbol] | [symbol] | [symbol] | [symbol] | [symbol] | [symbol] | [symbol] | [symbol] | [symbol] | [symbol] | [symbol] | [symbol] |
| | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| | | [symbol] | [symbol] | | | | | | | | | | | | |
| | | [symbol] | | | | | | | | | | | | | |
| | | [symbol] | [symbol] | | | | | | | | | | | | |
| | | [symbol] | | | | | | | | | | | | | |
| | | [symbol] | | | | | | | | | | | | | |
| | | [symbol] | [symbol] | [symbol] | [symbol] | [symbol] | [symbol] | [symbol] | [symbol] | [symbol] | [symbol] | [symbol] | [symbol] | [symbol] | [symbol] |
| | | [symbol] | | | | | | | | | | | | | |
| | [symbol] | [symbol] | [symbol] | | | | | | | | | | | [symbol] | |
| | | [symbol] | [symbol] | [symbol] | | | | | | | | | | | |
| | | [symbol] | [symbol] | | [symbol] | [symbol] | [symbol] | [symbol] | [symbol] | [symbol] | | [symbol] | | | |
| | | [symbol] | [symbol] | | | | | | | | | | | | |
| | | [symbol] | [symbol] | | | | | | | | | | | | [symbol] |
| | [symbol] | | | [symbol] | [symbol] | [symbol] | [symbol] | [symbol] | [symbol] | [symbol] | [symbol] | [symbol] | [symbol] | [symbol] | [symbol] |
| | [symbol] | | | [symbol] | [symbol] | [symbol] | [symbol] | [symbol] | [symbol] | [symbol] | [symbol] | [symbol] | [symbol] | [symbol] | [symbol] |
| | [symbol] | | | [symbol] | [symbol] | [symbol] | [symbol] | [symbol] | [symbol] | [symbol] | [symbol] | [symbol] | [symbol] | [symbol] | [symbol] |
| | [symbol] | | | | | | | | | | | | | | |
| [symbol] | | | [symbol] | | | | | | | | | | | | |
| | [symbol] | | [symbol] | [symbol] | [symbol] | [symbol] | [symbol] | [symbol] | [symbol] | [symbol] | [symbol] | [symbol] | [symbol] | [symbol] | [symbol] |
| | [symbol] | | [symbol] | [symbol] | [symbol] | [symbol] | [symbol] | [symbol] | [symbol] | [symbol] | [symbol] | [symbol] | [symbol] | [symbol] | [symbol] |
| | [symbol] | | [symbol] | [symbol] | [symbol] | [symbol] | [symbol] | [symbol] | [symbol] | [symbol] | [symbol] | [symbol] | [symbol] | [symbol] | [symbol] |
| | [symbol] | | [symbol] | [symbol] | [symbol] | [symbol] | [symbol] | [symbol] | [symbol] | [symbol] | [symbol] | [symbol] | [symbol] | [symbol] | [symbol] |
| | [symbol] | | [symbol] | [symbol] | [symbol] | [symbol] | [symbol] | [symbol] | [symbol] | [symbol] | [symbol] | [symbol] | [symbol] | [symbol] | [symbol] |

[symbol]

indicates data missing or illegible when filed

1. A thermally conductive silicone composition that is applied in a liquid state to a substrate, the composition comprising:
a component (A) that is a diorganopolysiloxane having an alkenyl group bonded to a silicon atom, with a viscosity at 25° C. of 10 mPa·s or more and 1,000,000 mPa·s or less;
a component (B) that is a diorganopolysiloxane having a hydrogen atom bonded to a silicon atom, with a viscosity at 25° C. of 10 mPa·s or more and 1,000,000 mPa·s or less;
a component (C) that is a thermally conductive filler;
a component (D) that is a silicone resin having at least one alkenyl group within one molecule, with a number-average molecular weight of 1,000 or more; and
a component (E) that is an addition reaction catalyst, wherein
a content of the component (C) is 300 parts by mass or more and 2,000 parts by mass or less relative to 100 parts by mass of a total amount of the components (A) and (B), and
a content of the component (D) is 1 part by mass or more relative to 100 parts by mass of the total amount of the components (A) and (B).

2. The thermally conductive silicone composition according to claim 1, wherein the component (D) has one or more alkenyl groups bonded to silicon atoms within one molecule and contains a silicone resin constituted of an MQ unit containing an R²₃SiO_{1/2} unit (M unit) and an SiO_{1/2} unit (Q unit).

3. The thermally conductive silicone composition according to claim 1 or 2, wherein when the total amount of the components (A) and (B) is 100 parts by mass, a multiplicative product of an amount of the component (D) contained in parts by mass with the number-average molecular weight of the component (D) is 3,000 or more.

4. The thermally conductive silicone composition according to any one of claims 1 to 3, wherein the component (C) is a thermally conductive filler selected from the group consisting of a metal, an oxide, a hydroxide, and a nitride.

5. The thermally conductive silicone composition according to any one of claims 1 to 4, comprising no organosilicon compound having one or more alkenyl groups and one or more alkoxy groups bonded to silicon atoms within one molecule.

6. A method for improving a resiliency of a cured product obtained by curing a thermally conductive silicone composition, the method comprising:
adding a component (D) that is a silicone resin having a number-average molecular weight of 1,000 or more to a thermally conductive silicone composition that contains a component (A) that is a diorganopolysiloxane having an alkenyl group bonded to a silicon atom, with a viscosity, at 25° C., of 10 mPa·s or more and 1,000,000 mPa·s or less, a component (B) that is a diorganopolysiloxane having a hydrogen atom bonded to a silicon atom, with a viscosity, at 25° C., of 10 mPa·s or more and 1,000,000 mPa·s or less, a component (C) that is a thermally conductive filler, and a component (E) that is an addition reaction catalyst;
applying the resulting thermally conductive silicone composition in a liquid state to a substrate; and
curing the thermally conductive silicone composition to obtain the cured product with an improved resiliency.

7. A method for producing a gap filler, comprising:
applying, to a substrate, a thermally conductive silicone composition in a liquid state, the composition containing
a component (A) that is a diorganopolysiloxane having an alkenyl group bonded to a silicon atom, with a viscosity at 25° C. of 10 mPa·s or more and 1,000,000 mPa·s or less,
a component (B) that is a diorganopolysiloxane having a hydrogen atom bonded to a silicon atom, with a viscosity at 25° C. of 10 mPa·s or more and 1,000,000 mPa·s or less,
a component (C) that is a thermally conductive filler,
a component (D) that is a silicone resin having at least one alkenyl group within one molecule, with a number-average molecular weight of 1,000 or more, and
a component (E) that is an addition reaction catalyst, wherein
a content of the component (C) is 300 parts by mass or more and 2,000 parts by mass or less relative to 100 parts by mass of a total amount of the components (A) and (B), and
a content of the component (D) is 1 part by mass or more relative to 100 parts by mass of the total amount of the components (A) and (B); and
curing the applied thermally conductive silicone composition.

8. A gap filler comprising a cured product of a thermally conductive silicone composition, wherein:
the composition containing
a component (A) that is a diorganopolysiloxane having an alkenyl group bonded to a silicon atom, with a viscosity at 25° C. of 10 mPa·s or more and 1,000,000 mPa·s or less,
a component (B) that is a diorganopolysiloxane having a hydrogen atom bonded to a silicon atom, with a viscosity at 25° C. of 10 mPa·s or more and 1,000,000 mPa·s or less,
a component (C) that is a thermally conductive filler,
a component (D) that is a silicone resin having at least one alkenyl group within one molecule, with a number-average molecular weight of 1,000 or more, and
a component (E) that is an addition reaction catalyst;
the gap filler exhibits an improved resiliency due to the component (D) added to the composition; and
a content of the component (C) is 300 parts by mass or more and 2,000 parts by mass or less, and a content of the component (D) is 1 part by mass or more and 10 parts by mass or less, relative to 100 parts by mass of a total amount of the components (A) and (B) in the thermally conductive silicone composition.

9. An electronic device comprising the gap filler according to claim 8.
